(19) United States
(12) Patent Application Publication
(10) Pub. No.: US 2025/0183198 A1
(43) Pub. Date: Jun. 5, 2025

(54) CONDUCTIVE CONNECTOR AND SOCKET

(71) Applicant: United Precision Technologies Co., Ltd., Tokyo (JP)

(72) Inventors: Norio HAMAUCHI, Tokyo (JP); Shuji KUNIOKA, Tokyo (JP); Hideki SATO, Tokyo (JP); Satoshi OSAWA, Tokyo (JP)

(73) Assignee: United Precision Technologies Co., Ltd., Tokyo (JP)

(21) Appl. No.: 18/509,298

(22) PCT Filed: Mar. 14, 2022
(86) PCT No.: PCT/JP2022/011362

§ 371 Date: Jan. 30, 2025

(30) Foreign Application Priority Data
May 27, 2021 (JP) 2021-089048

(51) Int. Cl. H01L 23/58; G01R 1/04; H01R 13/24

(52) U.S. Cl. CPC H01L 23/58; G01R 1/0416; H01R 13/2407

(57) ABSTRACT

To provide a conductive connector that is easy to manufacture and has a low disconnection risk. This conductive connector comprising a non-conductive elastic body and a reticulated fiber body comprising a covered region with a surface covered by metal is manufactured through the covering of the periphery of the non-conductive elastic body with the reticulated fiber body such that the reticulated fiber body is in a C-shape. The reticulated fiber body has, for example, alternatingly arranged uncovered regions not covered with metal and covered regions.

### TECHNICAL FIELD

The present invention relates to a conductive connector and a socket, and more particularly to a conductive connector and a socket used for a connector for an electronic device, a socket for a semiconductor, and the like.

### BACKGROUND ART

Patent Literature 1 discloses a contact probe that is arranged between a pair of conductive members facing each other to electrically connect the conductive members, and that includes a substantially U-shaped wiring member including a bundle of copper wires in a shape of connecting a contact part in contact with one of the conductive members and a contact part in contact with the other via an intermediate part, and a covering member manufactured by molding a block-shaped rubbery elastic body having a structure in which a portion other than the contact parts in the wiring member is buried.

[Patent Document 1] Abstract and Paragraphs [0032], [0049], and of Japanese Provisional Patent Publication No. 2015-036664

### SUMMARY OF INVENTION

### Technical Problem

However, although the block-shaped rubbery elastic body having the structure in which the portion other than the contact parts in the wiring member is buried covers the wiring member in the contact probe disclosed in Patent Literature 1, it is not easy to manufacture the contact probe having such a structure.

Furthermore, it is difficult for the wiring member to follow a displacement of the block-shaped rubbery elastic body, and thus excessive stress is likely to be applied only to some portions. Therefore, there is a problem that disconnection is likely to occur at these portions with use. There is also a problem that the contact parts in the wiring member are likely to be separated from the covering member due to a structure.

Therefore, an object of the present invention is to provide a conductive connector that does not cause such an inconvenience.

### Solution to Problem

In order to achieve the object described above, a conductive connector and a socket of the present invention include:
a non-conductive elastic body; and
a reticulated fiber body including a covered region with a surface covered by metal,
in which a periphery of the non-conductive elastic body is covered with the reticulated fiber body such that the reticulated fiber body is in a C-shape.

Note that, when the reticulated fiber body has alternatingly arranged uncovered regions not covered with metal and covered regions, the reticulated fiber body can be suitably used for a semiconductor device in which connection objects are arranged two-dimensionally or three-dimensionally.

The reticulated fiber body can be a fiber body in which an uncovered region not covered with metal is formed on a metal fiber covered with metal.

The uncovered region is preferably formed by a chemical treatment or a mechanical treatment.

### DESCRIPTION OF EMBODIMENTS

Hereinafter, embodiments of the present invention will be described with reference to the drawings. Note that, for convenience of description, description may be made using notation such as up, down, left, and right on the basis of the drawings, but it should be noted that the notation is merely relative and not absolute. Furthermore, it should also be noted that the drawings give priority to convenience of description, and dimensional ratios are not aligned between the drawings.

### First Embodiment

FIGS. 1A to 1E are schematic configuration diagrams of a conductive connector 1000 of a first embodiment of the present invention. The conductive connector 1000 is roughly divided into a reticulated fiber body 100 and a non-conductive elastic body 200 described below.

Note that FIG. 1A illustrated at the center is a right side view, FIG. 1B illustrated above FIG. 1A is a plan view, FIG. 1C illustrated below FIG. 1A is a bottom view, FIG. 1D illustrated on the left of FIG. 1A is a front view, and FIG. 1E illustrated on the right of FIG. 1A is a rear view. For convenience of description, the non-conductive elastic body 200 is not illustrated in FIG. 1E. Furthermore, although a left side view is not illustrated in FIG. 1, the left side view is symmetrical to the right side view.

As will be described later with reference to FIG. 4, the reticulated fiber body 100 can include a covered region 10 with a surface covered with metal containing a noble metal, and an uncovered region 20 not covered with metal. The covered region 10 faces a central region 10A illustrated in FIG. 1E, and the uncovered region 20 faces a peripheral region 20A in FIG. 1E.

Note that the entire reticulated fiber body 100 may be used as the covered region 10, so that the uncovered region 20 does not have be formed. However, when the uncovered region 20 is formed, for example, there is an advantage that it is possible to avoid the conductive connectors 1000 adjacent to each other from coming into contact with each other and short-circuiting when objects of contact with the conductive connectors 1000 are arranged in relatively short gaps.

The reticulated fiber body 100 has such a reticulated shape that a surface of the reticulated fiber body 100 facing the conductive elastic body 200 can be brought into full contact with the conductive elastic body 200. Moreover, for example, viscosity of the conductive elastic body 200 before curing is set at 500 mPa to 100,000 mPa, preferably 5,000 mPa to 50,000 mPa, more preferably 11,000 mPa to 14,000 mPa, depending on a size of a mesh of the reticulated fiber body 100, and the conductive elastic body 200 is allowed to enter the mesh, so that, in combination with the anchoring effect, the reticulated fiber body 100 can implement high adhesion to the conductive elastic body 200.

In addition, folded portions 110 are formed at upper and lower ends of the covered region 10 of the reticulated fiber body 100. The folded portions 110 also contribute to the adhesion between the reticulated fiber body 100 and the conductive elastic body 200. Note that, although FIG. 1 illustrates a state where the folded portions 110 are folded back by 180 degrees, the folding angle is not limited thereto, and may be, for example, about 120 degrees to 150 degrees. Furthermore, a size and the number of the folded portions 110 are also not limited to those illustrated in FIG. 1. Moreover, it is not essential to form the folded portions 110 in the covered region 10 in the first place.

As illustrated in FIG. 1A, the reticulated fiber body 100 has a generally C-shape, and thus has a spring property. Furthermore, although an upper surface and a lower surface of the reticulated fiber body 100 have portions parallel to each other, the C-shape referred to in the present specification is not strictly limited to this aspect, and therefore, referring to FIG. 1A, the reticulated fiber body 100 includes, for example, a case where an upper side is entirely curved. It is preferable that the shape of the reticulated fiber body 100 is a shape that can secure a large number of contact surfaces according to a shape of the object of contact.

The conductive connector 1000 can be used for inspection of a semiconductor device or the like. In this case, one of the upper surface and the lower surface of the reticulated fiber body 100 is brought into contact with an electrode terminal of an electronic component such as the semiconductor device, and the other is brought into contact with an electrode terminal of an electronic component inspection device. When a voltage is applied to the normal semiconductor device in this state, a current flows toward the inspection device through the covered region 10 of the reticulated fiber body 100.

As illustrated in FIG. 1A, an upper surface, a front surface, and a lower surface of the non-conductive elastic body 200 are covered with the reticulated fiber body 100 generally in the C-shape. The non-conductive elastic body 200 can include, for example, a silicon resin material, but can also be another resin material such as thermoplastic polyurethane (TPU) other than silicon as long as conditions of being non-conductive and having elasticity are satisfied.

In a case where the conductive connector 1000 is used for inspection of the semiconductor device, force is physically applied in the state of being in contact with each of the terminals described above. With this configuration, the non-conductive elastic body 200 is deformed to absorb the force. Such an operation principle is the same as that in the case of using the contact probe of Patent Literature 1.

However, since the reticulated fiber body 100 has only one corner portion on a lower side, stress applied thereto is limited, and the conductive connector 1000 may reliably have the C-shape without the corner portion, or may be as illustrated in order to, for example, increase and stabilize a placement surface when the conductive connector 1000 is placed on a substrate of the semiconductor device or the like.

Note that, in the present specification, as application of the conductive connector 1000, the case of the inspection device of the semiconductor device has been mainly described as an example, but the application of the conductive connector 1000 is not limited thereto, and the conductive connector 1000 can also be used for internal wiring of the semiconductor device or the like itself. In this case, it is sufficient that the conductive connector 1000 is connected to a wiring board or the like included in the semiconductor device or the like by a conductive adhesive, reflow soldering, or the like.

In this case, for example, in the case of soldering, a temperature only needs to be raised to about 260° C. Thus, when the material of the non-conductive elastic body 200 is a material having heat resistance to about 280° C., the conductive connector 1000 can also be connected to the substrate of the semiconductor device or the like by soldering.

FIG. 2 is a perspective view obtained by extracting a part of the covered region 10 of the reticulated fiber body 100 constituting the conductive connector 1000 illustrated in FIG. 1. The reticulated fiber body 100 can be a woven fabric, a non-woven fabric, or the like, for example, an insulating material.

The reticulated fiber body 100 is manufactured by knitting a plurality of fibers 5 arranged in a lattice. A thickness of the reticulated fiber body 100 is considered to be, for example, about 5 μm to 200 μm, preferably about 10 μm to 150 μm, and more preferably about 20 μm to 100 μm. The fiber 5 itself can be any insulating material (non-conductive fiber) having flexibility, and for example, a fiber appropriately selected from a glass fiber, a chemical fiber, a carbon fiber, and the like can be used as the fiber 5.

A surface of each fiber 5 illustrated in FIG. 2 is covered with metal, and the covered region 10 is formed thereon. Note that, as the metal mentioned here, a conductive metal such as gold, silver, platinum, or an alloy containing these as a main component, for example, can be used. Furthermore, specifications such as a diameter and strength of the fiber 5 are not particularly limited, but the metal itself can be appropriately selected to have a thickness of about 0.1 μm to 20 μm, preferably about 2 μm to 10 μm, and a hardness of 1 or more.

A method of manufacturing the reticulated fiber body 100 is not limited. For example, the fibers 5 in a state where the covered regions 10 are not formed may be woven in a lattice, and thereafter, regions where the covered regions 10 are desired to be formed may be brought into contact with a metal plating solution or a metal gas.

Alternatively, the fibers 5 covered with metal in advance may be woven in a lattice, and thereafter, regions where the uncovered regions 20 are desired to be formed may be formed by etching or the like using an etching solution corresponding to the metal. Note that, in this case, it is necessary to use an etching solution under a condition that the fibers 5 themselves are not dissolved.

Although it is possible to manufacture the reticulated fiber body 100 including the covered region 10 and the uncovered region 20 by any method, particularly, in a case where the reticulated fiber body 100 does not have the uncovered region 20 and has only the covered region 10, adopting the latter method is preferable because manufacturing efficiency is high.

Note that the uncovered region 20 is not necessarily formed by etching, and may be formed by a chemical treatment other than etching. Examples of such a treatment include mechanical treatments such as sandblasting and ion irradiation.

### Second Embodiment

FIG. 3 is a schematic perspective view of a part of a conductive connector 1000 of a second embodiment of the present invention. The conductive connector 1000 has a shape in which the conductive connector 1000 illustrated in FIG. 1 is continuously and repeatedly arranged two-dimensionally in a linear manner. Note that the conductive connector 1000 may have a shape in which the conductive connector 1000 illustrated in FIG. 1 is continuously and repeatedly arranged two-dimensionally in a planar manner.

In other words, the conductive connector 1000 illustrated in FIG. 1 can also be manufactured by manufacturing the conductive connector 1000 illustrated in FIG. 3 once and appropriately cutting the conductive connector 1000 into round slices at uncovered regions 20. Note that it is sufficient that the number and sizes of a covered region 10 and the uncovered region 20 are appropriately selected according to the number, a size, a dimension, and the like of an electrode terminal of an inspection object.

FIG. 4 is an explanatory view of a reticulated fiber body 100 constituting the conductive connector 1000 illustrated in FIG. 3. FIG. 4A is a rear view corresponding to FIG. 1E, and FIG. 4B is a perspective view of a state also including a non-conductive elastic body 200. Also in the reticulated fiber body 100 according to the present embodiment, folded portions 110 can be provided at appropriate intervals. Note that the conductive connector 1000 illustrated in FIG. 4 does not have a corner portion in the reticulated fiber body 100.

Note that the non-conductive elastic body 200 has generally a rectangular parallelepiped shape, but has upper and lower end portions each having an uneven shape. This uneven shape occurs in a case where the conductive connector 1000 is manufactured using a jig 3000 illustrated in FIG. 6A described later, and is not essential for the conductive connector 1000.

FIG. 5 is a perspective view illustrating a state where a plurality of the conductive connectors 1000 illustrated in FIG. 4 is mounted on a socket 2000. The socket 2000 includes a socket main body 2100 on which the plurality of conductive connectors 1000 is mounted, and positioning pins 2200 provided at four corners of the socket main body 2100.

In the example illustrated in FIG. 5, for example, a state where the conductive connectors 1000 each having the seven covered regions 10 are arranged in 14 rows and two columns in the socket main body 2100 is indicated, but all these numbers are merely examples.

FIGS. 6A to 6D are schematic views of a process of manufacturing the conductive connector 1000 illustrated in FIG. 4. Note that the process of manufacturing the conductive connector 1000 illustrated in FIGS. 6A to 6D is merely an example, and the process is not limited thereto. For example, the conductive connector 1000 may be manufactured by manufacturing the reticulated fiber body 100 including the covered region 10 and the uncovered region 20, separately manufacturing the non-conductive elastic body 200, and bonding them by using a conductive or non-conductive adhesive or the like. In this case, it is preferable that the adhesive or the like enters a mesh of the reticulated fiber body 100. Furthermore, it is also preferable that the adhesive has the heat resistance described above because application thereof is not limited.

FIG. 6A illustrates the jig 3000 for manufacturing the conductive connector 1000. The jig 3000 generally has a substantially rectangular parallelepiped shape. On an upper surface of the jig 3000, side walls are formed along both long sides. Together with the upper surface of the jig 3000, these side walls constitute a flow path 3200 into which a resin to be the non-conductive elastic body 200 is poured. Furthermore, a comb portion including a plurality of protrusions 3100 is formed on each of the side walls.

FIG. 6B illustrates the reticulated fiber body 100 including the covered regions 10 and the uncovered regions 20. It is sufficient that the reticulated fiber body 100 is manufactured by the method described with reference to FIG. 2. Note that, here, although the reticulated fiber body 100 is drawn so as to already have a C-shape, this is merely for making it easy to image the non-conductive elastic body 200.

FIG. 6C illustrates a state where the reticulated fiber body 100 illustrated in FIG. 6B is attached to the jig 3000 illustrated in FIG. 6A, a resin is poured into the flow path 3200, the resin reaches the mesh of the reticulated fiber body 100, and then the resin is cured to form the non-conductive elastic body 200. Note that the reticulated fiber body 100 is attached to the jig 3000 such that each of the uncovered regions 20 and each of the protrusions 3100 correspond to each other.

FIG. 6D illustrates a state where the completed conductive connector 1000 is removed from the jig 3000. Referring to FIG. 6D, it can be seen that the non-conductive elastic body 200 is covered with the reticulated fiber body 100 in the C-shape.

Note that, in order to manufacture the conductive connector 1000 illustrated in FIG. 1, a tooth of a slicer can be inserted between the protrusions 3100 in the state of FIG. 6C and the conductive connector 1000 can be cut into round slices at the uncovered regions 20. As a matter of course, as illustrated in FIG. 6D, the conductive connector 1000 can be cut into round slices at the uncovered regions 20 of the conductive connector 1000 removed from the jig 3000.

Furthermore, in a case where the conductive connectors 1000 are arranged two-dimensionally in a planar manner, it is sufficient to use a configuration in which, for example, the covered regions 10 are formed in a matrix shape and the jigs 3000 illustrated in FIG. 6A are continuously arranged in a short direction.

As described above, the conductive connector 1000 of each embodiment of the present invention is easy to manufacture, has a low disconnection risk, and can be used semi-permanently.

### BRIEF DESCRIPTION OF DRAWINGS

FIG. 1 is a schematic configuration diagram of a conductive connector 1000 of a first embodiment of the present invention.

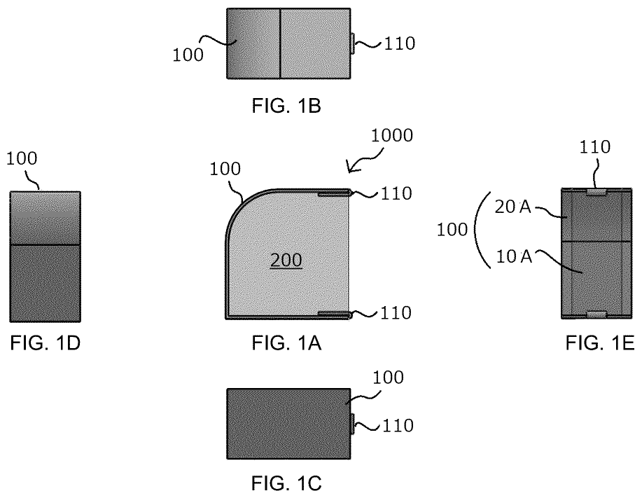

FIG. 2 is a perspective view obtained by extracting a part of a covered region 10 of a reticulated fiber body 100 constituting the conductive connector 1000 illustrated in FIG. 1.

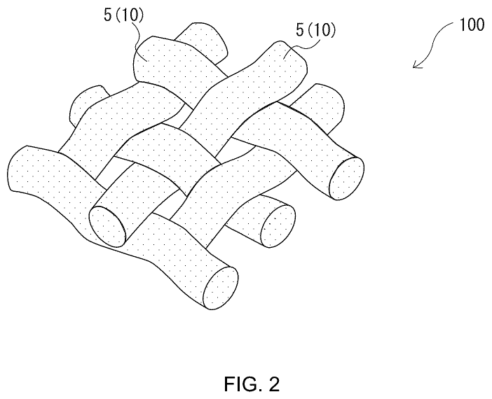

FIG. 3 is a schematic perspective view of a part of a conductive connector 1000 of a second embodiment of the present invention.

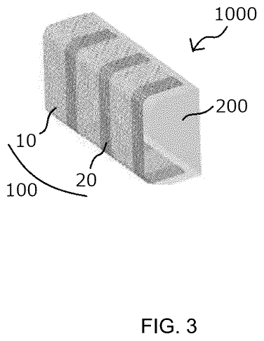

FIG. 4 is an explanatory view of a reticulated fiber body 100 constituting the conductive connector 1000 illustrated in FIG. 3.

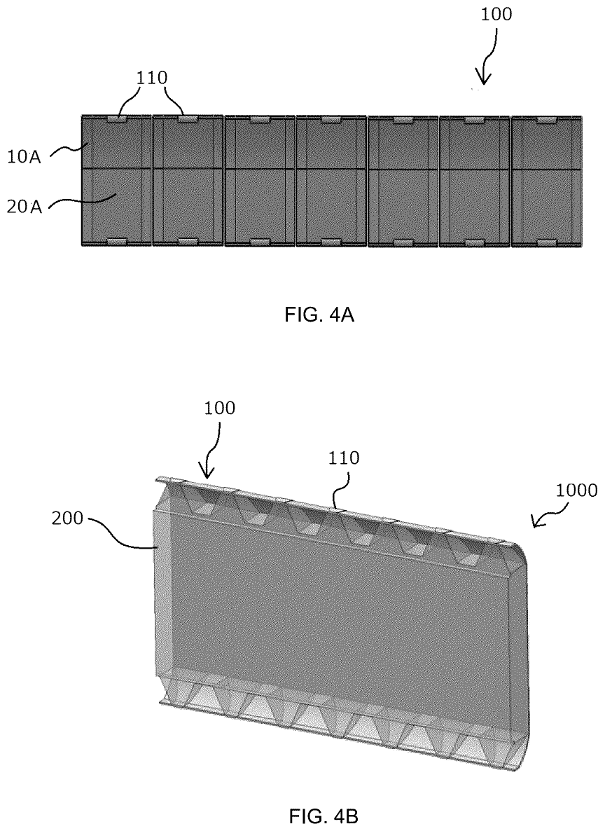

FIG. 5 is a perspective view illustrating a state where a plurality of the conductive connectors 1000 illustrated in FIG. 4 is mounted on a socket 2000.

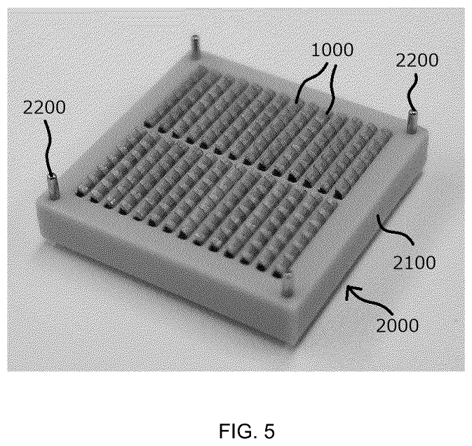

FIG. 6 is a schematic view of a process of manufacturing the conductive connector 1000 illustrated in FIG. 4.

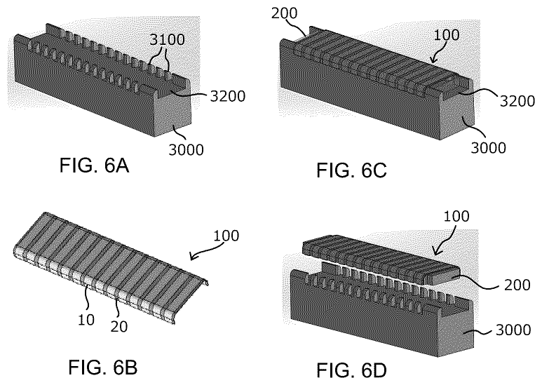

### REFERENCE SIGNS LIST

5 Fiber
10 Covered region
20 Uncovered region
100 Reticulated fiber body
200 Non-conductive elastic body
1000 Conductive connector
2000 Socket
2100 Socket main body
2200 Positioning pin

1. A conductive connector comprising:
a non-conductive elastic body; and
a reticulated fiber body including a covered region with a surface covered by metal and an uncovered region not covered with metal by metal,
wherein a periphery of the non-conductive elastic body is covered with the reticulated fiber body such that the reticulated fiber body is in a C-shape, and
the uncovered region is formed by a chemical treatment or a mechanical treatment.

2. The conductive connector according to claim 1,
wherein, in the reticulated fiber body, an uncovered region not covered with metal and the covered region are alternatingly arranged.

3. (canceled)

4. A socket on which a plurality of the conductive connectors according to claim 1 is mounted.

5. A socket on which a plurality of the conductive connectors according to claim 2 is mounted.

6. (canceled)

7. A semiconductor device in which the conductive connector according to claim 1 is used for internal wiring.

8. A semiconductor device in which the conductive connector according to claim 2 is used for internal wiring.
